(19) United States
(12) Patent Application Publication
(10) Pub. No.: US 2026/0025992 A1
(43) Pub. Date: Jan. 22, 2026

(54) REDUCED POWER CONSUMPTION FOR PROGRAMMING OR ERASING A SPLIT-GATE MEMORY CELL, MEMORY CELL AND MANUFACTURING METHOD

(71) Applicant: STMicroelectronics International N.V., Geneva (CH)

(72) Inventor: Christian RIVERO, Peynier (FR)

(73) Assignee: STMicroelectronics International N.V., Geneva (CH)

(21) Appl. No.: 19/268,360

(22) Filed: Jul. 14, 2025

(30) Foreign Application Priority Data
Jul. 17, 2024 (FR) FR2407819

(51) Int. Cl. H10B 41/35

(52) U.S. Cl. CPC H10B 41/35

(57) ABSTRACT

A non-volatile memory device includes a memory cell having a split gate state transistor and a vertical type select transistor buried in a semiconductor substrate. The memory device includes structure designed to increase the mobility of the carriers in a semiconductor channel of the vertical type select transistor during a programming or erasing operation of the memory cell by hot carriers.

### PRIORITY CLAIM

This application claims the priority benefit of French Application for Patent No. FR2407819, filed on Jul. 17, 2024, the content of which is hereby incorporated by reference in its entirety to the maximum extent allowable by law.

### TECHNICAL FIELD

Embodiments relate to non-volatile memories, in particular split-gate non-volatile memories, and a completely buried select transistor (including the source) and, in particular, reduced power consumption for programming or erasing of such memories by hot carriers.

### BACKGROUND

A split-gate memory cell has a state transistor having a floating gate separated from the channel of the transistor by a gate oxide layer and topped by a control gate electrically isolated from the floating gate.

Such a floating gate state transistor can be programmed or erased: by the injection or extraction of electrical charges into or from the floating gate of the transistor by tunnelling (Fowler-Nordheim effect) through the gate oxide, or by hot carrier (electrons or holes) injection into the floating gate.

When using the Fowler-Nordheim effect for programming or erasing, a large electric field is applied between the substrate of the state transistor and the floating gate. This involves applying a high potential difference, usually around 15 V, which also depends on the thickness of the gate oxide, generated using a large charge pump, which is therefore expensive in terms of surface area.

It is therefore generally preferably to use hot carrier injection.

When using the hot carrier effect to program or erase a split-gate state transistor associated with a select transistor buried in the substrate, the vertical current of the electrons is used which pass through the channel of the select transistor (which is then is saturation mode) to create electron/hole pairs on the side of the drain of the select transistor which is close to the floating gate of the state transistor.

All that is needed is to apply a positive voltage to the control gate to attract the electrons in the event of programming or a negative voltage to attract the holes in the event of erasing.

It is the kinetic energy of the hot carriers (which has been transmitted to them by the electrons of the vertical channel of the select transistor) which on its own enables these hot carriers (electrons or holes) to be injected into the floating gate and the electric field, and consequently the potential difference applied to the terminals of the gate oxide located beneath the floating gate is very small relative to that used in the Fowler-Nordheim effect.

It is necessary to reduce the power consumption during a programming or erasing operation of a non-volatile memory cell by hot carriers, in particular a split-gate non-volatile memory cell with a completely buried select transistor.

### SUMMARY

According to one embodiment, it is proposed to increase the mobility of the carriers, for example electrons, in the channel of the select transistor, in order to increase the density (number) of hot carriers created.

This increase in mobility can be achieved by reducing the resistance of the channel and increasing the current density.

To this end, it is advantageously proposed to localize the conduction of the electrons in a tensile-strained silicon layer (in the direction of conduction), which increases the mobility of the electrons in the channel during a programming or erasing operation.

This increase in mobility results in an increase in the number of hot carriers created, which enables the power consumption needed to program or erase the memory cell to be reduced.

This energy reduction results in, for example, a reduction in programming or erasing time, if the same voltage values are applied to the different electrodes of the memory cell as those applied generally in the prior art.

It would also be possible to translate this energy reduction into a reduction in the voltage values applied, while maintaining the same programming or erasing time.

However, such a solution is more complex to implement in terms of adjusting the electrical conditions from one memory device to another, which may contain different densities of memory cells.

In addition, the first aforementioned solution (reducing the programming or erasing time) is preferred because it can be applied to all memory devices whatever their memory density.

According to one aspect, a non-volatile memory device is proposed comprising a memory cell having a split gate state transistor and a vertical type select transistor buried in a semiconductor substrate, and means designed to increase the mobility of the carriers (for example electrons) in the semiconductor channel of the select transistor during a programming or erasing operation of the memory cell by hot carriers.

A vertical type select transistor buried in the substrate can have its source region on the surface (i.e., emerging at the surface of the substrate) and its drain region deep in the substrate.

Alternatively, the vertical type select transistor can have a non-surface source region (i.e., deep in the substrate, typically deeper than the drain region).

This alternative (non-surface source region) is more advantageous in terms of surface area and makes it possible to have two select transistors sharing a shared buried gate region and being able to be associated with two twin memory cells, which is not possible for a vertical type select transistor with a surface source region.

According to one embodiment, said means include in the semiconductor channel, a silicon region located between a gate oxide region and a region of a silicon germanium alloy.

As the lattice parameter of the silicon germanium is greater than that of silicon, the silicon that will be deposited by epitaxy on this silicon germanium will undergo a positive deformation (biaxial and isotropic) which causes tensile strain in the silicon and consequently an increase in the mobility of the carriers (electrons for example) in this silicon layer.

According to one embodiment, the thickness of the silicon region is comprised between 5 and 30 nanometers and the thickness of the region of said silicon germanium alloy is comprised between 5 and 20 nanometers, preferably less than 15 nanometers.

According to one embodiment, the silicon germanium alloy is a GeₓSi₍₁₋ₓ₎ alloy where x is comprised between 0.3 and 0.9.

According to another aspect, a non-volatile memory device is proposed comprising a memory cell having a split gate state transistor and a vertical type select transistor buried in a semiconductor substrate and preferably having a non-surface source region.

The select transistor has a semiconductor channel having a silicon region located between a gate oxide region and a region of a silicon germanium alloy.

According to one embodiment, the device comprises another memory cell, the twin of said memory cell, the two twin memory cells having the same structure and each having a select transistor buried in the semiconductor substrate and with an identical structure.

The two select transistors have a shared buried gate region surrounded by a stack having a silicon layer surrounded by a gate oxide layer and a layer of said silicon germanium alloy.

The silicon layer, the gate oxide layer and the layer of said silicon alloy respectively include the two silicon regions, the two gate oxide regions and the two regions of said silicon germanium alloy of the channels of the two select transistors of the two twin memory cells.

According to one embodiment, the thickness of each silicon region is comprised between 5 and 30 nanometers and the thickness of each region of said silicon germanium alloy is comprised between 5 and 20 nanometers.

According to one embodiment, the silicon germanium alloy is a GeₓSi₍₁₋ₓ₎ alloy where x is comprised between 0.3 and 0.9.

According to one embodiment, the device comprises a memory plane having rows and columns of memory cells, and a structure with one bit line per column, all the twin memory cells of a column being connected to the bit line of said column.

Alternatively, the memory plane can have a structure with two bit lines per column, two twin memory cells of a column being connected to different bit lines out of the two bit lines of said column, while two memory cells of said column that are adjacent but not twins are connected to the same bit line of said column.

According to another aspect, a method is proposed for reducing power consumption during a programming or erasing operation by hot carriers of a memory cell having a split gate state transistor and a vertical type select transistor buried in a semiconductor substrate and preferably having a non-surface source region.

The method according to this aspect comprises increasing the mobility of the carriers in the semiconductor channel of the select transistor during said programming or erasing operation.

According to one embodiment, the increase in mobility comprises the application of tensile strain to a silicon region of the channel by an underlying region of a silicon germanium alloy, the silicon region being between this silicon germanium alloy region and a gate oxide region.

The thickness of the silicon region is, for example, comprised between 5 and 30 nanometers and the thickness of the region of said silicon germanium alloy is, for example, comprised between 5 and 20 nanometers.

The silicon germanium alloy is, for example, a GeₓSi₍₁₋ₓ₎ alloy where x is comprised between 0.3 and 0.9.

According to another aspect, a method is proposed for manufacturing a non-volatile memory device comprising producing a non-volatile memory cell.

Producing the non-volatile memory cell comprises producing in and on a semiconductor substrate a split gate state transistor and producing a vertical type select transistor buried in the semiconductor substrate and preferably having a non-surface source region.

Producing the select transistor comprises: forming a trench in the semiconductor substrate; epitaxially growing a layer of a silicon germanium alloy on the walls of the trench; epitaxially growing a silicon layer on the layer of said silicon germanium alloy; forming a gate oxide layer on the silicon layer; and filling the trench with polysilicon so as to form a gate region of the select transistor.

According to one embodiment, the method comprises producing in and on a semiconductor substrate, next to said state transistor, another split gate state transistor associated with another select transistor, the two select transistors having the same gate region surrounded by the stack formed by the underlying layer of silicon germanium alloy, the silicon layer and the gate oxide layer, so as to form two twin memory cells.

The thickness of the silicon layer is, for example, comprised between 5 and 30 nanometers and the thickness of the layer of said silicon germanium alloy is comprised between 5 and 20 nanometers.

The silicon germanium alloy is, for example, a GeₓSi₍₁₋ₓ₎ alloy where x is comprised between 0.3 and 0.9.

### BRIEF DESCRIPTION OF THE DRAWINGS

Other advantages and features of the invention will become apparent upon examining the detailed description of non-limiting embodiments and implementations, and from the appended drawings, wherein:

FIG. 1 is a schematic diagram of a split-gate non-volatile memory cell;

FIG. 2 is a cross-sectional view of an integrated circuit structure for the split-gate non-volatile memory cell;

FIG. 3 is a schematic diagram of a memory plane structure;

FIG. 4 is a schematic diagram of a memory plane structure;

FIGS. 5 and 6 show in more detail the structure of each channel of the corresponding select transistor of the memory cell;

FIG. 7 shows an embodiment of a method for reducing power consumption during a programming or erasing operation; and

FIGS. 8 to 11 shows steps in a method for manufacturing a non-volatile memory device.

### DETAILED DESCRIPTION

In FIG. 1, the reference M designates a split-gate non-volatile memory cell, for example of the select transistor type having a vertical gate buried in the substrate of an integrated circuit.

More specifically, the memory cell M has a state transistor T having a floating gate FG topped by a control gate CG connected to a gate control line CGL.

The drain (D) of the state transistor T is connected to a bit line BL while the source(S) of the state transistor T is connected to the drain of a select transistor ST.

The select transistor ST has a gate CSG connected to a word line WL.

The source(S) of the select transistor ST is connected to a source line SL.

As shown in FIG. 2, each state transistor of a memory cell cooperates with the select transistor ST which is of the vertical type and buried in the substrate SB.

The channel ZCH of the state transistor has the reference ZCH.

The select transistors ST connected to the two state transistors Ti,j and Ti+1,j each have a vertical channel ZCV and a shared buried vertical select gate CSG.

The two memory cells Mi,j and Mi+1,j are therefore referred to as “twins”.

These two twin cells Mi,j and Mi+1,j belong to the same column j and to both rows i and i+1.

It should be noted that in order to simplify the figure, the contact connecting the shared buried gate CSG to the corresponding word line WLi,i+1 is not shown.

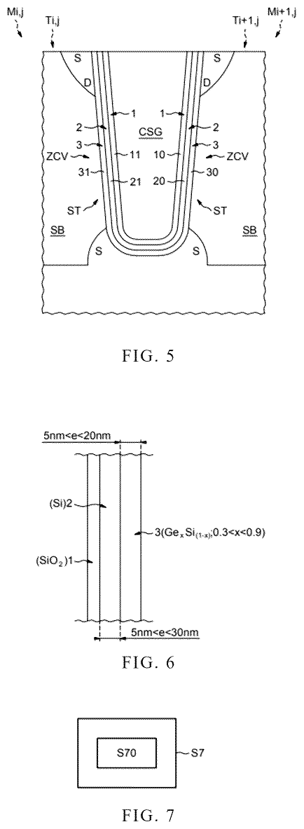

Similarly, the gate oxide that surrounds the buried gate CSG and separates it from each channel ZCV, as well as the structure of each channel ZCV, are not shown in FIG. 2, but are shown in FIGS. 5 and 6.

The source region S of each select transistor ST is non-surface, buried in the substrate SB deeper than the drain region D of the corresponding select transistor.

The semiconductor region that contains the drain region D of a select transistor ST also contains the source region S of the state transistor connected to this select transistor.

The state transistor is advantageously a depletion mode transistor here.

The channel ZCH of the state transistor is advantageously a surface channel such that it may be possible to block the conduction of the channel by applying an acceptable control voltage to the control gate of the state transistor.

With such memory cells, different memory plane structures are possible (i.e., a structure with only one bit line per column or a structure with two (or double) bit lines per column).

The embodiments herein are compatible with these two types of memory plane structure.

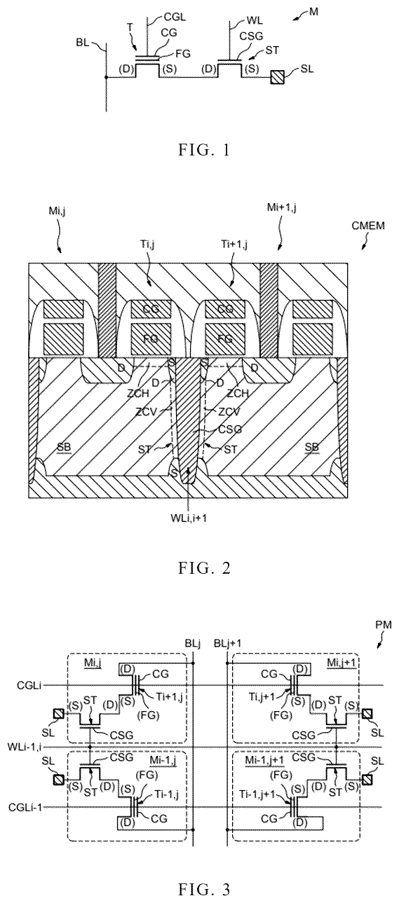

By way of example, FIG. 3 shows a memory plane PM structure with only one bit line per column and comprising memory cells Mi,j; Mi,j+1; M−1,j; Mi−1,j+1 of the type mentioned above.

The memory cells Mi,j and Mi−1,j having a shared select gate CSG are twins. Similarly, the memory cells Mi,j+1 and Mi−1,j+1 are twin memory cells.

The memory cells Mi,j and Mi,j+1 of rank “i” belong to the row of rank i of the memory plane and are connected to a word line WLi−1,i and a gate control line CGLi.

The memory cells Mi−1,j and Mi−1,j+1 of rank “i−1” belong to the row of rank “i−1” of the memory plane and are connected to the word line WLi−1,i and to a gate control line CGLi−1.

The memory cells Mi,j and Mi−1,j of rank “j” belonging to column j are readable and writeable via a single bit line BLj and the memory cells Mi,j+1 and Mi−1,j+1 of rank “j−1” are readable and writeable via a single bit line BLj+1.

The drain regions (D) of the state transistors Ti,j and Ti−1,j are connected to the bit line BLj and the drain terminals of the state transistors Ti,j+1 and Ti−1,j+1 are connected to the bit line BLj+1. The control gates CG of the transistors Ti,j and Ti,j+1 are connected to the gate control line CGLi and the control gates CG of the floating gate transistors Ti−1,j and Ti−1,j+1 are connected to the gate control line CGLi−1.

Each floating gate transistor has its source terminal(S) connected to a source line SL via the select transistor ST.

The shared select gates CSG of twin memory cells are connected to the word line WLi−1,i.

In read mode, a zero read voltage can be applied to the control gate CG of the state transistor and a positive voltage can be applied to the bit line BL.

As the state transistor is a depletion mode transistor with a negative threshold voltage, it is normally conductive for a blank memory cell (i.e., when no charge is present in the floating gate).

A state transistor of an erased memory cell will be conductive while the state transistor of a programmed memory cell will be blocked.

Furthermore, a floating gate transistor is programmed or erased here by injecting hot carriers (electrons for programming and holes for erasing) into the floating gate of the transistor.

More specifically, a memory cell is erased using hot carriers (hot holes) by combining a positive voltage applied to the substrate with a negative voltage applied to the control gate of its floating gate state transistor.

In terms of the twin cell, if it is not desirable for it to be simultaneously erased, a positive voltage is applied to the control gate of its state transistor.

A memory cell can be programmed using hot electrons, for example, by applying a positive voltage to the bit line in question, by applying a zero voltage to the substrate, and a positive voltage to the control gate of its floating gate state transistor.

Such a memory cell to be programmed is selected by applying a positive voltage greater than the threshold voltage of the state transistor to the word line in question.

In terms of the twin cell, if it is not desirable for it to be simultaneously programmed, a weakly negative or zero programming inhibition voltage is applied to the control gate of its state transistor.

Finally, as mentioned above, a memory cell is read by applying a zero voltage to the control gate CG of its state transistor, and a positive voltage to the corresponding bit line.

Such a memory cell to be read is selected by applying a positive voltage greater than the threshold voltage of the state transistor to the word line in question.

In practice, in read mode, a zero voltage will be applied to all the cells of the memory plane.

Therefore, two selected twin cells will be read simultaneously.

If, however, it is not desirable for the twin cells to be read simultaneously, a negative read inhibition voltage will be applied to the control gate of the twin cell that is not to be read.

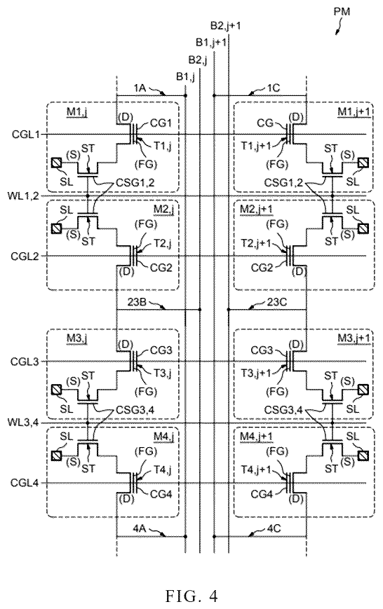

FIG. 4 shows a memory plane and twin memory cell structure known as “double bit lines” (two bit lines per column).

In such a structure, each memory cell can be read independently of its twin memory cell by using the bit line to which it is connected and to which its twin memory cell is not connected without the need to apply a negative read inhibition voltage to the gate control line of the twin memory cell.

Similarly, each memory cell can be programmed independently of its twin memory cell by using the bit line to which it is connected and to which its twin memory cell is not connected without the need to apply a negative programming inhibition voltage to the gate control line of the twin memory cell.

The memory plane PM comprises rows and columns of memory cells, eight memory cells M1,j, M2,j, M3,j, M4,j, M1,j+1, M2,j+1, M3,j+1, M4,j+1 being shown here. Each memory cell has a state transistor, respectively referenced T1,j, T2,j, T3,j, T4,j, T1,j+1, T2,j+1, T3,j+1, T4,j+1, and a select transistor ST connected between a source plane SL and the state transistor.

The memory cells M1,j, M2,j, M3,j, M4,j belong to a column of rank j and the memory cells M1,j+1, M2,j+1, M3,j+1, M4,j+1 belong to an adjacent column of rank j+1. The memory cells M1,j, M1,j+1 belong to a first row of memory cells, and their state transistors T1,j, T1,j+1 have control gates CG1 connected to a shared gate control line CGL1. The memory cells M2,j, M2,j+1 belong to a second row of memory cells, and their state transistors T2,j, T2,j+1 have control gates CG2 connected to a shared gate control line CGL2. The memory cells M3,j, M3,j+1 belong to a third row of memory cells, and their state transistors T3,j, T3,j+1 have control gates CG3 connected to a shared gate control line CGL3. The memory cells M4,j, M4,j+1 belong to a fourth row of memory cells, and their state transistors T4,j, T4,j+1 have control gates CG4 connected to a shared gate control line CGLA.

In the column of rank j, the memory cells M1,j, M2,j are twin memory cells and their select transistors ST have a shared select gate CSG1,2 connected to a shared word line WL1,2.

Similarly, the memory cells M3,j, M4,j are twin memory cells and their select transistors ST have a shared select gate CSG3,4 connected to a shared word line WL3,4.

In the column of rank j+1, the memory cells M1,j+1, M2,j+1 are twin memory cells and their select transistors ST have a shared select gate CSG1,2 connected to the word line WL1,2.

The memory cells M3,j+1, M4,j+1 are twin memory cells and their select transistors ST have a shared select gate CSG3,4 connected to the shared word line WL3,4.

The memory plane PM comprises two bit lines per column of memory cells. Thus, two bit lines B1,j, B2,j are attributed to the memory cells of the column of rank j, and two bit lines B1,j+1, B2,j+1 are attributed to the memory cells of the column of rank j+1.

Two twin memory cells are connected to different bit lines out of the two bit lines attributed to the column in which they are located, whilst two adjacent but not twin memory cells are connected to the same bit line.

Thus, in the column of rank j:
the drain terminal (D) of the state transistor T1,j is connected to the bit line B1,j via a conductive path 1A;
the drain terminal of the state transistor T2,j is connected to the bit line B2,j via a conductive path 23B;
the drain terminal of the state transistor T3,j is connected to the bit line B2,j via the conductive path 23B (the memory cell M2,j being adjacent to but not a twin of the memory cell M3,j); and
the drain terminal of the state transistor T4,j is connected to the bit line B1,j via a conductive path 4A.

In the column of rank j+1:
the drain terminal of the state transistor T1,j+1 is connected to the bit line B1,j+1 via a conductive path 1C;
the drain terminal of the state transistor T2,j+1 is connected to the bit line B2,j+1 via a conductive path 23D;
the drain terminal of the state transistor T3,j+1 is connected to the bit line B2,j+1 via the conductive path 23D (the memory cell M2,j+1 being adjacent to but not a twin of the memory cell M3,j+1); and
the drain terminal of the state transistor T4,j+1 is connected to the bit line B1,j+1 via a conductive path 4C.

Each memory cell can be read independently of its twin memory cell by means of the bit line to which it is connected and to which its twin memory cell is not connected. For example, after selecting the twin memory cells C3,j, C4,j by means of a selection voltage applied to the word line WL3,4 and after having applied a zero read voltage to the gate control line CGL3, the memory cell C3,j can be read via the bit line B2,j without the need to apply a negative read inhibition voltage to the gate control line CGL4 of the twin memory cell C4,j because this memory cell is not connected to the bit line B2,j but rather to the bit line B1,j.

Therefore, it is possible to apply a zero read voltage to the control gates of all the memory cells of the memory plane.

For programming, it is possible to apply the same positive voltage to the control gates of two twin cells, apply a positive voltage to the bit line to program the twin cell connected to this bit line and apply a zero voltage to the bit line connected to the other memory cell that is not to be programmed.

Reference is now made more specifically to FIGS. 5 and 6 to show in more detail the structure of each channel ZCV of the corresponding select transistor ST of the memory cell Mi,j and Mi+1,j shown in a highly schematic manner in FIG. 2.

The shared buried gate region CSG of the two select transistors ST is surrounded by a stack having a silicon (Si) layer 2 framed by a gate oxide layer 1 (for example silicon dioxide (SiO₂) and a layer 3 of a silicon germanium alloy (GeₓSi₍₁₋ₓ₎).

This stack includes, on the right-hand side of FIG. 5, a silicon region 20 surrounded by a gate oxide region 10 and a region 30 of the silicon germanium alloy, and includes, on the left-hand side of FIG. 5, a silicon region 21 surrounded by a gate oxide region 11 and a region 31 of the silicon germanium alloy.

The channel ZCV of the select transistor ST of the memory cell Mi+1,j thus has the silicon region 20 surrounded by the gate oxide region 10 and the germanium silicon region 30.

The channel ZCV of the select transistor ST of the memory cell Mi,j has the silicon region 21 surrounded by the gate oxide region 11 and the germanium silicon region 31.

In the semiconductor channel ZCV of the corresponding select transistor ST, the silicon region located between the gate oxide region and the region of the silicon germanium alloy forms means for increasing the mobility of the carriers, in this case electrons, in this semiconductor channel ZCV during a programming or erasing operation of the memory cell.

Indeed, the lattice parameter of the silicon germanium is greater than that of the silicon. Therefore, the silicon that will be deposited by epitaxy on the silicon germanium, as will be discussed in more detail below, will undergo a positive biaxial and isotropic deformation which causes tensile strain in the silicon and consequently an increase in the mobility of the hot carriers in this silicon layer.

This results in reduced power consumption during programming or erasing of the memory cell.

As a guide, for a non-volatile memory cell with a split gate and select transistor buried in the substrate and non-surface source, produced using a CMOS 40 nm technology, these means for increasing the mobility of the electrons in the channel of the select transistor result in a reduction of around 20% of the programming or erasing time, maintaining the same voltage values applied to the electrodes of the memory cell as those applied to a memory cell in the prior art.

As shown in FIG. 6, the thickness of the silicon layer 2, and therefore of each silicon region 20 and 21, is, for example, comprised between 5 nm and 30 nm.

The thickness of the silicon germanium layer 3 is comprised between 5 and 20 nm, for example less than 15 nm.

The value of x for the alloy GeₓSi₍₁₋ₓ₎ is, for example, comprised between 0.3 and 0.9.

FIG. 7 shows in a highly schematic manner an embodiment of a method for reducing power consumption during a programming or erasing operation by hot carriers of a memory cell having a split gate state transistor and a select transistor buried in a semiconductor substrate.

Generally, the method comprises increasing (step S7) the mobility of the carriers in the semiconductor channel of the select transistor during the programming or erasing operation of the memory cell.

This increase in mobility may comprise the application of tensile strain (step S70) to a silicon layer of the channel by an underlying layer of a silicon germanium alloy, this silicon layer being between this silicon germanium alloy layer and a gate oxide layer.

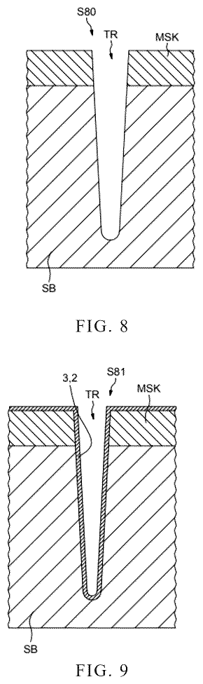

Reference is now made more specifically to FIGS. 8 to 11 to describe an embodiment of a method for manufacturing a non-volatile memory device according to the invention, and in particular an embodiment for forming the channel of each select transistor ST of two twin memory cells.

More specifically, in FIG. 8, in the semiconductor substrate SB of the integrated circuit intended to receive the memory device according to the invention, a trench TR is first of all produced (step S80) at the location of the future buried gate region.

This trench TR is obtained in a conventional manner known per se by etching through a mask MSK.

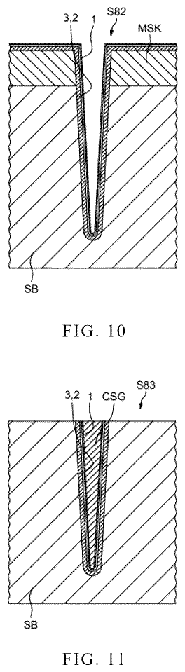

This is followed (step S81), as shown in FIG. 9, by a first epitaxial growth of the silicon germanium layer 2 on the walls of the trench TR, then a second epitaxial growth of the silicon layer 3 on the silicon germanium layer 2.

These steps of epitaxially growing a silicon germanium layer and then epitaxially growing a silicon layer are conventional steps known to a person skilled in the art.

Then, as shown in FIG. 10, the gate oxide layer 1 is formed (step S82) on the epitaxial silicon layer 2, for example by thermal growth.

Finally, after having performed (step S83) chemical-mechanical polishing of the mask MSK topped with part of the stack formed by the layers 3, 2 and 1, the buried gate region CSG is obtained, as shown in FIG. 11, filling the remainder of the trench TR surrounded by the stack formed by the layers of silicon germanium 2, silicon 3 and gate oxide 1.

The remainder of the formation of the select transistors includes, for example, forming the source and drain regions as well as the remainder of the formation of the twin memory cells, and producing the state transistors in particular. These steps are conventional and known per se by a person skilled in the art. This results in the formation of the structure shown in FIG. 2.

1. A non-volatile memory device, comprising:
a memory cell having a split gate state transistor and a vertical type select transistor buried in a semiconductor substrate; and
means for increasing mobility of carriers in a semiconductor channel of the vertical type select transistor during a programming or erasing operation of the memory cell by hot carriers.

2. The device according to claim 1, wherein said means for increasing comprises, in the semiconductor channel of the vertical type select transistor, a silicon region located between a gate oxide region and a region of a silicon germanium alloy.

3. The device according to claim 2, wherein a thickness of the silicon region is comprised between 5 and 30 nanometers and a thickness of the region of said silicon germanium alloy is comprised between 5 and 20 nanometers.

4. The device according to claim 2, wherein the silicon germanium alloy is a GeₓSi₍₁₋ₓ₎ alloy, where x is comprised between 0.3 and 0.9.

5. The device according to claim 2, wherein the vertical type select transistor includes a trench and wherein said trench has a first layer on sidewalls of the trench formed by said region of silicon germanium alloy, a second layer on the first layer formed by said silicon region, and a third layer on the second layer formed by the gate oxide region.

6. The device according to claim 2, wherein the silicon region is in tensile strain.

7. The device according to claim 1, wherein the vertical type select transistor has a non-surface source region.

8. A non-volatile memory device, comprising:
a first memory cell having a split gate state transistor and a vertical type select transistor buried in a semiconductor substrate;
wherein the vertical type select transistor has a semiconductor channel having a silicon region located between a gate oxide region and a region of a silicon germanium alloy.

9. The device according to claim 8, wherein the vertical type select transistor has a non-surface source region.

10. The device according to claim 8, comprising a second memory cell, which said second memory cell is a twin of said first memory cell, the first and second memory cells forming twin memory cells having a same structure with vertical type select transistors buried in the semiconductor substrate having an identical structure, the vertical type select transistors of the twin memory cells having a shared buried gate region surrounded by a stack having a silicon layer surrounded by a gate oxide layer and a layer of said silicon germanium alloy, the silicon layer, the gate oxide layer and the layer of said silicon germanium alloy respectively including the two silicon regions, the two gate oxide regions and the two regions of said silicon germanium alloy of the channels of the vertical type select transistors of the twin memory cells.

11. The device according to claim 10, comprising a memory plane having rows and columns of memory cells, and a structure with one bit line per column, wherein all twin memory cells of a column are connected to the bit line of said column.

12. The device according to claim 10, comprising a memory plane having rows and columns of memory cells, and a structure with two bit lines per column, wherein two twin memory cells of a column are connected to different bit lines out of the two bit lines of said column, while two memory cells of said column that are adjacent but not twin memory cells are connected to the same bit line of said column.

13. The device according to claim 10, wherein a thickness of each silicon region is comprised between 5 and 30 nanometers and a thickness of each region of said silicon germanium alloy is comprised between 5 and 20 nanometers.

14. The device according to claim 8, wherein the silicon germanium alloy is a GeₓSi₍₁₋ₓ₎ alloy, where x is comprised between 0.3 and 0.9.

15. The device according to claim 8, wherein the vertical type select transistor includes a trench and wherein said trench has a first layer on sidewalls of the trench formed by said region of silicon germanium alloy, a second layer on the first layer formed by said silicon region, and a third layer on the second layer formed by the gate oxide region.

16. The device according to claim 8, wherein the silicon region is in tensile strain

17. A method for reducing power consumption during a programming or erasing operation by hot carriers of a memory cell having a split gate state transistor and a vertical type select transistor buried in a semiconductor substrate, the method comprising increasing mobility of carriers in semiconductor channel of the vertical type select transistor during said programming or erasing operation.

18. The method according to claim 17, wherein increasing mobility comprises applying a tensile strain to a silicon region of the semiconductor channel by an underlying region of a silicon germanium alloy, the silicon region being between the silicon germanium alloy region and a gate oxide region.

19. The method according to claim 17, wherein a thickness of the silicon region is comprised between 5 and 30 nanometers and a thickness of the region of said silicon germanium alloy is comprised between 5 and 20 nanometers.

20. The method according to claim 17, wherein the silicon germanium alloy is a GeₓSi₍₁₋ₓ₎ alloy, where x is comprised between 0.3 and 0.9.

21. The method according to claim 17, wherein the vertical type select transistor has a non-surface source region.

22. A method for manufacturing a non-volatile memory device, comprising producing a non-volatile memory cell by:
producing in and on a semiconductor substrate a split gate state transistor; and
producing a vertical type select transistor buried in the semiconductor substrate;
wherein producing the vertical type select transistor comprises:
forming a trench in the semiconductor substrate;
epitaxially growing a layer of a silicon germanium alloy on walls of the trench;
epitaxially growing a silicon layer on the layer of said silicon germanium alloy;
forming a gate oxide layer on the silicon layer; and
filling the trench with polysilicon so as to form a gate region of the select transistor.

23. The method according to claim 22, wherein producing the vertical type select transistor includes producing a non-surface source region.

24. The method according to claim 23, comprising producing in and on a semiconductor substrate, next to said state transistor, another split gate state transistor associated with another select transistor, the two select transistors having the same gate region surrounded by the stack formed by the underlying layer of silicon germanium alloy, the silicon layer and the gate oxide layer, so as to form twin memory cells.

25. The method according to claim 22, wherein the thickness of the silicon layer is comprised between 5 and 30 nanometers and the thickness of the layer of said silicon germanium alloy is comprised between 5 and 20 nanometers.

26. The method according to claim 22, wherein the silicon germanium alloy is a GeₓSi₍₁₋ₓ₎ alloy, where x is comprised between 0.3 and 0.9.
